(19) United States
(12) Patent Application Publication
(10) Pub. No.: US 2025/0185516 A1
(43) Pub. Date: Jun. 5, 2025

(54) Piezoelectric Element, Liquid Ejection Head, And Printer

(71) Applicant: SEIKO EPSON CORPORATION, Tokyo (JP)

(72) Inventors: Yoshiki YANO, Chino (JP); Koji OHASHI, Matsumoto (JP); Yasuaki HAMADA, Chino (JP); Tsukasa HITOMI, Chino (JP); Daisuke NAGANO, Matsumoto (JP)

(21) Appl. No.: 18/961,852

(22) Filed: Nov. 27, 2024

(30) Foreign Application Priority Data
Nov. 30, 2023 (JP) 2023-202528

(51) Int. Cl. H10N 30/50; B41J 2/14; C01G 49/00; H10N 30/00; H10N 30/20; H10N 30/853

(52) U.S. Cl. CPC H10N 30/508; B41J 2/14274; C01G 49/0036; H10N 30/2047; H10N 30/708; H10N 30/8542; B41J 2002/14306; C01P 2002/50; C01P 2002/90; C01P 2006/40

(57) ABSTRACT

A piezoelectric element includes a first electrode and a second electrode and a piezoelectric layer provided between the first electrode and the second electrode, the piezoelectric layer including a plurality of layers containing a composite oxide having a perovskite structure containing potassium, sodium, and niobium; wherein among the plurality of layers including the composite oxide, a first layer closest to the first electrode is preferred orientation in a first orientation, which is a {100} plane orientation in a film thickness direction, among the plurality of layers including the composite oxide, a second layer closest to the second electrode is, in an in-plane direction intersecting the film thickness direction, a mix of the first orientation and a second orientation, which is a {110} plane orientation, and is not preferred orientation in either the first orientation or the second orientation.

The present application is based on, and claims priority from JP Application Serial Number 2023-202528, filed Nov. 30, 2023, the disclosure of which is hereby incorporated by reference herein in its entirety.

### BACKGROUND

### 1. Technical Field

The present disclosure relates to a piezoelectric element, a liquid ejection head, and a printer.

### 2. Related Art

A piezoelectric element used in a liquid ejection head, or the like of an inkjet printer is configured, for example, by sandwiching a piezoelectric layer made of a piezoelectric material exhibiting an electromechanical conversion function between two electrodes.

For example, JP-A-2014-36035 describes a piezoelectric element including a KNN piezoelectric layer containing potassium, sodium, and niobium as main components.

In the piezoelectric element as described above, it is desired to reduce the leakage current.

### SUMMARY

In one aspect of the present disclosure, the piezoelectric element includes:
a first electrode and a second electrode and
a piezoelectric layer provided between the first electrode and the second electrode, the piezoelectric layer including a plurality of layers containing a composite oxide having a perovskite structure containing potassium, sodium, and niobium; wherein
among the plurality of layers including the composite oxide, a first layer closest to the first electrode is preferred orientation in a first orientation, which is a {100} plane orientation in a film thickness direction,
among the plurality of layers including the composite oxide, a second layer closest to the second electrode is, in an in-plane direction intersecting the film thickness direction, a mix of the first orientation and a second orientation, which is a {110} plane orientation, and is not preferred orientation in either the first orientation or the second orientation.

In one aspect of the present disclosure, the liquid ejection head includes
the piezoelectric element;
a channel forming substrate in which a pressure generating chamber whose volume is changed by the piezoelectric element is formed; and
a nozzle plate in which a nozzle hole communicating with the pressure generating chamber is formed.

In one aspect of the present disclosure, the printer includes:
the liquid ejection head;
a transport mechanism configured to perform relative movement a recording medium with respect to the liquid ejection head; and
a control section that controls the liquid ejection head and the transport mechanism.

### BRIEF DESCRIPTION OF THE DRAWINGS

FIG. 1 is a cross-sectional view schematically showing a piezoelectric element according to present embodiment.

FIG. 2 is an exploded perspective view schematically showing the liquid ejection head according to the present embodiment.

FIG. 3 is a plan view schematically showing the liquid ejection head according to the present embodiment.

FIG. 4 is a cross-sectional view schematically showing the liquid ejection head according to the present embodiment.

FIG. 5 is a perspective view schematically showing the printer according to the present embodiment.

FIG. 6 is a table showing experimental results of Examples 1 and 2 and Comparative Examples 1 to 4.

FIG. 7 is a pole figure of Examples 1 and 2 and Comparative Example 1 by EBSD.

FIG. 8 is a domain observation map of Examples 1 and 2 and Comparative Example 1 by EBSD.

FIG. 9 shows metallographical micrographs of Example 1 and Comparative Example 3.

### DESCRIPTION OF EMBODIMENTS

Hereinafter, preferred embodiments of the present disclosure will be described in detail with reference to the drawings. Note that the embodiments described below do not unduly limit the contents of the disclosure described in the appended claims. In addition, all of the configurations described below are not necessarily essential constituent elements of the disclosure.

### 1. Piezoelectric Element

### 1.1. Configuration

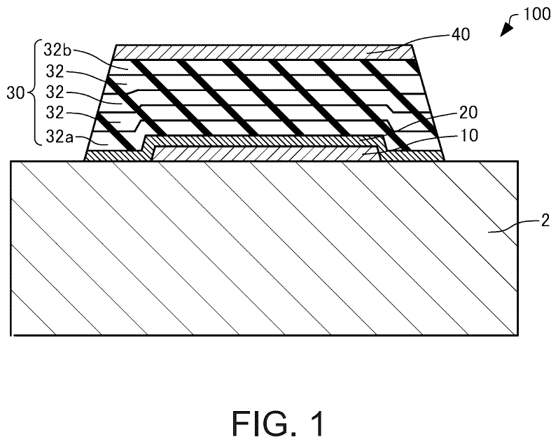

First, a piezoelectric element according to the present embodiment will be described with reference to the drawings. FIG. 1 is a cross-sectional view schematically showing a piezoelectric element 100 according to the present embodiment.

As shown in FIG. 1, the piezoelectric element 100 includes, for example, a first electrode 10, an orientation control layer 20, a piezoelectric layer 30, and a second electrode 40. The piezoelectric element 100 is provided on a base body 2.

The base body 2 is, for example, a flat plate formed of a semiconductor, an insulator, or the like. The base body 2 may be a single layer or a laminated body in which a plurality of layers is laminated. The internal structure of the base body 2 is not limited as long as the upper surface has a planar shape, and the base body 2 may have a structure in which a empty-space or the like is formed therein.

The base body 2 may include a diaphragm that is deformed by the operation of the piezoelectric layer 30. The diaphragm is, for example, a silicon oxide layer, a zirconium oxide layer, or a laminated body in which a zirconium oxide layer is provided on a silicon oxide layer.

The first electrode 10 is provided on the base body 2. The first electrode 10 is provided between the base body 2 and the orientation control layer 20. The shape of the first electrode 10 is, for example, a layered shape. The thickness of the first electrode 10 is, for example, not less than 5 nm and not more than 300 nm, and preferably not less than 50 nm and not more than 200 nm.

The first electrode 10 is, for example, a titanium layer, a platinum layer, or an iridium layer. The first electrode 10 may be formed by stacking a titanium layer, a platinum layer, and an iridium layer in this order from the base body 2 side. The titanium layer improves, for example, the adhesion between the base body 2 and the platinum layer. The first electrode 10 is one electrode for applying a voltage to the piezoelectric layer 30.

The orientation control layer 20 is provided on the first electrode 10. The orientation control layer 20 is provided between the first electrode 10 and the piezoelectric layer 30. In the illustrated example, the orientation control layer 20 is further provided on the base body 2. The thickness of the orientation control layer 20 is, for example, not less than 5 nm and not more than 100 nm, and preferably not less than 10 nm and not more than 50 nm.

The orientation control layer 20 includes a composite oxide having a perovskite structure containing bismuth (Bi), iron (Fe), titanium (Ti), and lead (Pb). The orientation control layer 20 is, for example, a bismuth lead ferrate titanate ((Bi, Pb) (Fe, Ti) O3: BFTP) layer. The orientation control layer 20 may be a BFTP layer to which an additive is added. The orientation control layer 20 controls the orientation of the piezoelectric layer 30.

The piezoelectric layer 30 is provided on the orientation control layer 20. The piezoelectric layer 30 is provided between the first electrode 10 and the second electrode 40. In the illustrated example, the piezoelectric layer 30 is provided between the orientation control layer 20 and the second electrode 40. The thicknesses of the piezoelectric layer 30 is, for example, not less than 100 nm and not more than 3 μm, and preferably not less than 200 nm and not more than 2 μm. The piezoelectric layer 30 is deformed when a voltage is applied between the first electrode 10 and the second electrode 40.

The piezoelectric layer 30 includes a plurality of crystalline layers 32. The piezoelectric layer 30 is formed of, for example, the plurality of crystalline layers 32. The number of crystalline layers 32 is, for example, not less than 2 and not more than 30, and preferably not less than 3 and not more than 20. In the illustrated example, five crystalline layers 32 are provided. The crystalline layers 32 have a thickness of, for example, not less than 10 nm and not more than 200 nm, and preferably not less than 30 nm and not more than 150 nm.

The crystalline layers 32 are layers including a composite oxide with a perovskite structure that includes potassium (K), sodium (Na), and niobium (Nb). The crystalline layers 32 are, for example, a potassium sodium niobate ((K, Na)NbO3:KNN) layer. The crystalline layers 32 may be KNN layers to which an additive is added. Examples of the additive include lithium (Li), manganese (Mn), and copper (Cu). The content of the additives in the crystalline layers 32 is, for example, 10 mol % or less, and preferably 5 mol % or less. The additive may be unevenly distributed in the grain boundary of the crystalline layers 32.

Hereinafter, the structure of the crystalline layers 32 is treated as a pseudocubic crystal. However, this is an expression for simplifying the description, and the crystalline layers 32 may have a crystal structure with low symmetry such as a tetragonal crystal or an orthorhombic crystal. Furthermore, even if the crystalline layers 32 have a structure with lower symmetry, it does not lead to any contradiction.

The second electrode 40 is provided on the piezoelectric layer 30. Although not shown, the second electrode 40 may be further provided on the side surface of the piezoelectric layer 30 and on the base body 2 as long as the second electrode 40 is electrically separated from the first electrode 10. The second electrode 40 has, for example, a layered shape. The thickness of the second electrode 40 is, for example, not less than 15 nm and not more than 300 nm.

The second electrode 40 is, for example, a platinum layer, a titanium layer, or an iridium layer. The second electrode 40 may be formed by stacking a plurality of the layers exemplified above. The second electrode 40 is the other electrode for applying a voltage to the piezoelectric layer 30.

### 1.2. Orientation and the Like

### 1.2.1. First Layer

A first layer 32a of the crystalline layers 32 is the layer closest to the first electrode 10 of the crystalline layers 32. In the illustrated example, the first layer 32a is provided on the orientation control layer 20. The first layer 32a is in contact with the orientation control layer 20. The first layer 32a is provided between the orientation control layer 20 and a second layer 32b. The orientation control layer 20 is provided between the first electrode 10 and the first layer 32a. The orientation control layer 20 controls the orientation of the first layer 32a.

The first layer 32a is preferred orientation in a first orientation, which is a {100} plane orientation, in the film thickness direction. The film thickness direction is the stacking direction of the crystalline layers 32. In the illustrated example, the film thickness direction is a direction perpendicular to the upper surface of the base body 2.

Here, “the A-layer is preferred orientation in the first orientation in the film thickness direction” means that the orientation ratio of the first orientation of the A-layer is 80% or more in the film thickness direction. This also applies to the case where the “film thickness direction” is replaced with the “in-plane direction”.

The orientation ratio can be measured by electronic back scattering diffraction (EBSD). In the first layer 32a, the orientation ratio of the first orientation in the film thickness direction may be 85% or more, 90% or more, 95% or more, or 100%. The first layer 32a may be preferred orientation in the (001) plane in the film thickness direction.

The first layer 32a may be preferred orientation in the first orientation in an in-plane direction crossing the film thickness direction. Specifically, the in-plane direction is a direction orthogonal to the film thickness direction. The first layer 32a may be preferred orientation in the (001) plane in the in-plane direction.

In the first layer 32a, a first orientation, which is a {100} plane orientation, a second orientation, which is a {110} plane orientation, and a third orientation, which is a {111} plane orientation, may be mixed in the in-plane direction. The first layer 32a may not be preferred orientation in any of the first orientation, the second orientation, and the third orientation in the in-plane direction.

Hereinafter, in the A-layer, a case where the first orientation, the second orientation, and the third orientation are mixed in the in-plane direction and the A-layer is preferred orientation in none of the first orientation, the second orientation, and the third orientation is also referred to as “random orientation”. This also applies to the case where the “in-plane direction” is replaced with the “film thickness direction”.

### 1.2.2. Second Layer

The second layer 32b of the plurality of crystalline layers 32 is the layer closest to the second electrode 40 of the plurality of crystalline layers 32. In the illustrated example, the second layer 32b is in contact with the second electrode 40. The second layer 32b is provided between the first layer 32a and the second electrode 40.

The second layer 32b may be randomly oriented in the film thickness direction. In the second layer 32b, the orientation ratio of the first orientation in the film thickness direction may be 85% or more, 90% or more, 95% or more, or 100%. The second layer 32b may be preferred orientation in the (001) plane in the film thickness direction.

In the second layer 32b, a first orientation which is a {100} plane orientation and a second orientation which is a {110} plane orientation are mixed in the in-plane direction. Further, the second layer 32b may have a third orientation which is a {111} plane orientation in the in-plane direction. The second layer 32b is not preferred orientation in any of the first orientation, the second orientation, and the third orientation in the in-plane direction. The second layer 32b may be randomly oriented in the in-plane direction.

The domain diameter in the in-plane direction of the second layer 32b is, for example, 7 μm or less, preferably 5.5 μm or less, more preferably 5.01 μm or less, furthermore preferably 1 μm or less, and still furthermore preferably 0.22 μm or less. The domain diameter in the in-plane direction of the second layer 32b is measured by EBSD.

### 1.3. Operational Effects

The piezoelectric element 100 includes the first electrode 10, the second electrode 40, and the piezoelectric layer 30 provided between the first electrode 10 and the second electrode 40, which has the plurality of crystalline layers 32 containing a composite oxide of a perovskite structure containing potassium, sodium, and niobium. The first layer 32a, which is the closest of the plurality of crystalline layers 32 to the first electrode 10, is preferred orientation in a first orientation, which is a {100} plane orientation, in the film thickness direction. The second layer 32b, which is the closest of the plurality of crystalline layers 32 to the second electrode 40, is a mixture of the first orientation and the second orientation, which is the {110} plane orientation, and is not preferred orientation in either the first orientation or a second orientation in the in-plane direction, which intersects the film thickness direction.

As described above, in the piezoelectric element 100, since the first layer 32a is preferred orientation in the first orientation in the film thickness direction, it is possible to reduce the stresses generated at the grain boundary with a different orientation from the first orientation. Therefore, cracking can be suppressed. Cracking is the cause of leak paths.

In the piezoelectric element 100, since the second layer 32b is not preferred orientation in either the first orientation or the second orientation in the in-plane direction, it is possible to suppress the generation of a grain boundary which may become a leak path connected from the first electrodes to the second electrodes in the film thickness direction. The stress is dispersed, and crack starting points due to the local stress concentration can be reduced.

As described above, the leakage current can be reduced in the piezoelectric element 100.

In the piezoelectric element 100, in the second layer 32b, the first orientation, the second orientation, and the third orientation, which is the {111} plane orientation, are mixed in the in-plane direction, and the second layer 32b is not preferred orientation in the third orientation. By this, in the piezoelectric element 100, it is possible to suppress the generation of a grain boundary, which may become a leak path connected from the first electrode to the second electrode in the film thickness direction.

In the piezoelectric element 100, the second layer 32b is preferred orientation in the first orientation in the film thickness direction. Therefore, in the piezoelectric element 100, in the second layer 32b, it is possible to reduce the stresses generated at the grain boundary with a different orientation from the first orientation.

The piezoelectric element 100 further includes the orientation control layer 20 provided between the first electrode 10 and the first layer 32a and including bismuth, iron, titanium, and lead. Therefore, in the piezoelectric element 100, the orientation of the first layer 32a can be controlled.

In the piezoelectric element 100, the domain diameter in the in-plane direction of the second layer 32b is 5.01 μm or less. Therefore, in the piezoelectric element 100, the second layer 32b can be randomly oriented in the in-plane direction.

In the piezoelectric element 100, the domain diameter in the in-plane direction of the second layer 32b is 0.22 μm or less. Therefore, in the piezoelectric element 100, the second layer 32b can be randomly oriented in the in-plane direction.

### 2. Method for Manufacturing Piezoelectric Element

Next, a method of manufacturing the piezoelectric element 100 according to the present embodiment will be described with reference to the drawings.

As shown in FIG. 1, the base body 2 is prepared. Specifically, the silicon oxide layer is formed by thermally oxidizing the silicon substrate. Next, a zirconium layer is formed on the silicon oxide layer by a sputtering method or the like, and the zirconium layer is thermally oxidized to form a zirconium oxide layer. The base body 2 can be prepared by the steps described above.

Next, the first electrode 10 is formed on the base body 2. The first electrode 10 is formed by, for example, a sputtering method, a vacuum vapor deposition method, or the like. Next, the first electrode 10 is patterned by, for example, photolithography and etching.

Next, the orientation control layer 20 is formed on the first electrode 10 and the base body 2. The orientation control layer 20 is formed by, for example, a sol gel method or a chemical solution deposition (CSD) method such as metal organic deposition (MOD).

Specifically, first, a precursor solution is blended by dissolving or dispersing a metal complex containing bismuth, a metal complex containing iron, a metal complex containing titanium, and a metal complex containing lead in an organic solvent. Next, the precursor solution is applied onto the first electrode 10 by a spin coating method to form a precursor layer. Next, the precursor layer is heated at, for example, 130° C. or more and 250° C. or less to be dried for a certain period of time, and the dried precursor layer is further heated at, for example, 300° C. or more and 450° C. or less to be held for a certain period of time to be degreased. Next, the degreased precursor layer is crystallized by sintering at, for example, 550° C. or more and 800° C. or less. As described above, the orientation control layer 20 made of the BFTP layer can be formed.

Next, the piezoelectric layer 30 is formed on the orientation control layer 20. The piezoelectric layer 30 is formed by, for example, a CSD method.

Specifically, first, for example, a precursor solution is blended by dissolving or dispersing a metal complex containing potassium, a metal complex containing sodium, a metal complex containing lithium, a metal complex containing niobium, a metal complex containing manganese, and a metal complex containing copper in an organic solvent.

Examples of the metal complex containing potassium include potassium 2-ethylhexanoate and potassium acetate. Examples of the metal complex containing sodium include sodium 2-ethylhexanoate and sodium acetate. Examples of the metal complex containing lithium include lithium 2-ethylhexanoate. Examples of the metal complex containing niobium include niobium 2-ethylhexanoate, niobium ethoxide, pentaethoxyniobium, and pentabutoxyniobium. Examples of the metal complex containing manganese include manganese 2-ethylhexanoate and manganese acetate. Examples of the metal complex containing copper include copper 2-ethylhexanoate. Two or more kinds of metal complexes may be used in combination. For example, potassium 2-ethylhexanoate and potassium acetate may be used in combination as the metal complex containing potassium.

Solvents include, for example, propanol, butanol, pentanol, hexanol, octanol, ethylene glycol, propylene glycol, octane, decane, cyclohexane, xylene, toluene, yetrahydrofuran, acetic acid, octylic acid, 2-n butoxyethanol, n-octane, 2-n ethylhexane, or a mixed solvent thereof.

Next, the prepared precursor solution is applied onto the orientation control layer 20 by a spin coating method or the like to form a precursor layer. Next, the precursor layer is heated at, for example, 130° C. or more and 250° C. or less to be dried for a certain period of time, and the dried precursor layer is further heated at, for example, 300° C. or more and 450° C. or less to be held for a certain period of time to be degreased. Next, the degreased precursor layer is crystallized by sintering at, for example, 550° C. or more and 800° C. or less.

By this, the crystalline layers 32 of the piezoelectric layer 30 can be formed. Then, the series of steps from the application of the precursor solution to sintering the precursor layer is repeated a plurality of times. By this, the piezoelectric layer 30 composed of a plurality of crystalline layers 32 can be formed.

In the step of forming the crystalline layers 32, a heating device used for drying and degreasing the precursor layer is, for example, a hot plate. A heating apparatus used for sintering the precursor layer is an infrared lamp annealing apparatus (rapid thermal annealing (RTA apparatus).

The RTA apparatus used in the sintering step has two lamps. In the sintering step, the base body 2 on which the precursor layer is formed is disposed between the two lamps. In other words, the sintering step is performed in a state where one lamp is disposed on each of the upper and lower sides of the base body 2 on which the precursor layer is formed.

Further, a sintering process is performed while flowing oxygen (O2). The oxygen flow cools in particular the upper part of the base body 2 on which the precursor layer has been formed. The mass flow rate of the oxygen flow is, for example, 1 SLPM or more and 10 SLPM or less, and preferably 2 SLPM or more and 5 SLPM or less.

Next, the second electrode 40 is formed on the piezoelectric layer 30. The second electrode 40 is formed by, for example, a sputtering method or a vacuum vapor deposition method. Next, the second electrode 40 and the piezoelectric layer 30 are patterned by, for example, photolithography and etching. The second electrode 40 and the piezoelectric layer 30 may be patterned in different steps.

Through the above steps, the piezoelectric element 100 can be manufactured.

### 3. Liquid Ejection Head

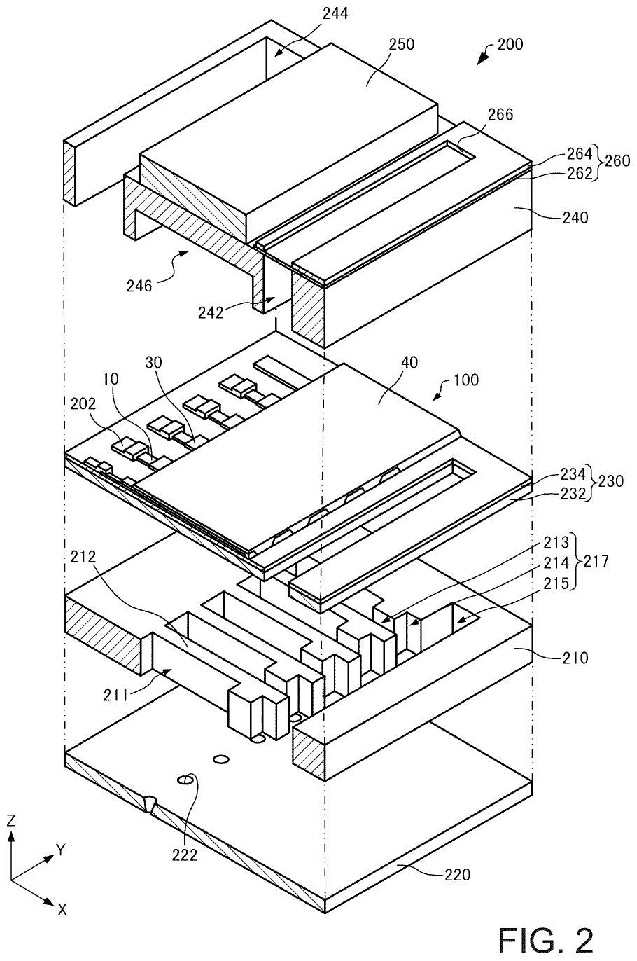

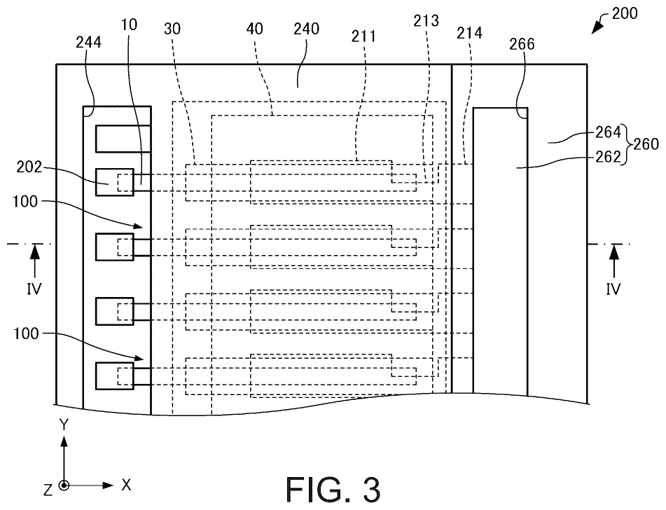

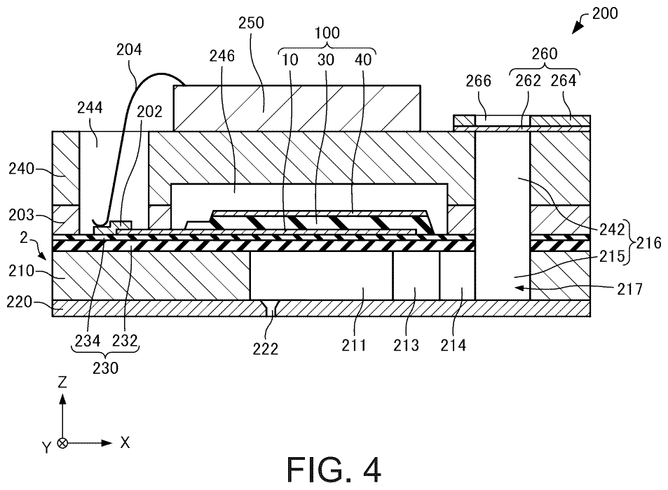

Next, a Liquid ejection head according to the present embodiment will be described with reference to the drawings. FIG. 2 is an exploded perspective view schematically showing a liquid ejection head 200 according to the present embodiment. FIG. 3 is a plan view schematically showing the liquid ejection head 200 according to the present embodiment. FIG. 4 is a cross-sectional view taken along the line IV-IV of FIG. 3 schematically showing the liquid ejection head 200 according to the present embodiment. In FIGS. 2 to 4, an X axis, a Y axis, and a Z axis are illustrated as three axes orthogonal to each other. In FIGS. 2 and 4, the piezoelectric element 100 is illustrated in a simplified manner.

As shown in FIGS. 2 to 4, the liquid ejection head 200 includes, for example, the base body 2, the piezoelectric element 100, a nozzle plate 220, a protection substrate 240, a circuit substrate 250, and a compliance substrate 260. The base body 2 includes a channel forming substrate 210 and a diaphragm 230. For convenience, the circuit substrate 250 is not shown in FIG. 3.

The channel forming substrate 210 is, for example, a silicon substrate. A pressure generating chamber 211 is formed in the channel forming substrate 210. The pressure generating chamber 211 is partitioned by a plurality of partitions 212. The pressure generating chamber 211 has its volume changed by the piezoelectric element 100.

A first communication path 213 and a second communication path 214 are formed in an end section of the +X axis direction of the pressure generating chamber 211 in the channel forming substrate 210. The first communication path 213 is configured such that an opening area thereof is reduced by narrowing an end section of the pressure generating chamber 211 in the +X axis direction from the Y axis direction. For example, the size of the second communication path 214 in the Y-axis direction is the same as the size of the pressure generating chamber 211 in the Y-axis direction. A third communication path 215 communicating with the plurality of second communication paths 214 is formed in the +X axis direction of the second communication path 214. The third communication path 215 constitutes a part of a manifold 216. The manifold 216 serves as a common liquid chamber for each of the pressure generating chamber 211. In this manner, the channel forming substrate 210 including a supply flow path 217 having the first communication path 213, the second communication path 214, and the third communication path 215, and the pressure generating chamber 211. The supply flow path 217 communicates with the pressure generating chamber 211 and supplies liquid to the pressure generating chamber 211.

The nozzle plate 220 is provided on one surface of the channel forming substrate 210. The material of the nozzle plate 220 is, for example, steel use stainless (SUS). The nozzle plate 220 is bonded to the channel forming substrate 210 by, for example, an adhesive or a thermal welding film. In the nozzle plate 220, a plurality of nozzle holes 222 are formed along the Y-axis. The nozzle hole 222 communicates with the pressure generating chamber 211 and ejects the liquid.

The diaphragm 230 is provided on the other surface of the channel forming substrate 210. The diaphragm 230 includes, for example, a silicon oxide layer 232 provided on the channel forming substrate 210, and a zirconium oxide layer 234 provided on the silicon oxide layer 232.

The piezoelectric element 100 is provided, for example, on the diaphragm 230. A plurality of piezoelectric elements 100 is provided. The number of piezoelectric elements 100 is not particularly limited. For convenience, the orientation control layer 20 is not shown in FIG. 4.

In the liquid ejection head 200, the diaphragm 230 and the first electrode 10 are displaced by the deformation of the piezoelectric layer 30 having an electromechanical conversion characteristic. In other words, in the liquid ejection head 200, the diaphragm 230 and the first electrode 10 substantially have a function as a diaphragm. The diaphragm 230 may be omitted, and only the first electrode 10 may function as the diaphragm. In a case where the first electrode 10 is directly provided on the channel forming substrate 210, the first electrode 10 is preferably protected by an insulating protective film or the like so that the first electrode 10 does not come into contact with the liquid.

The first electrode 10 is configured as an individual electrode which is independent for each pressure generating chamber 211. The size of the first electrode 10 in the Y-axis direction is smaller than the size of the pressure generating chamber 211 in the Y-axis direction. The size of the first electrode 10 in the X-axis direction is larger than the size of the pressure generating chamber 211 in the X-axis direction. In the X-axis direction, both end portions of the first electrode 10 are located outside both end sections of the pressure generating chamber 211. A lead electrode 202 is coupled to the −X axis direction end section of the first electrode 10.

For example, the size of the piezoelectric layer 30 in the Y-axis direction is larger than the size of the first electrode 10 in the Y-axis direction. The size of the piezoelectric layer 30 in the X-axis direction is, for example, larger than the size of the pressure generating chamber 211 in the X-axis direction. For example, the end section of the piezoelectric layer 30 in the +X axis direction is positioned on the outer side of the end section of the first electrode 10 in the +X axis direction. The end section of the first electrode 10 in the +X axis direction is covered with the piezoelectric layer 30. On the other hand, the end section of the piezoelectric layer 30 in the −X axis direction is positioned, for example, further inside than the end section of the first electrode 10 on the −X axis direction side. The end section of the first electrode 10 on the −X axis direction side is not covered with the piezoelectric layer 30.

For example, the second electrode 40 is continuously provided on the piezoelectric layer 30 and the diaphragm 230. The second electrode 40 is configured as a common electrode common to the plurality of piezoelectric elements 100.

The protection substrate 240 is bonded to the channel forming substrate 210 by an adhesive 203. A through hole 242 is formed in the protection substrate 240. In the illustrated example, the through hole 242 penetrates the protection substrate 240 in the Z-axis direction and communicates with the third communication path 215. The through hole 242 and the third communication path 215 constitute the manifold 216 serving as a common liquid chamber of the pressure generating chambers 211. Further, a through hole 244 penetrating the protection substrate 240 in the Z-axis direction is formed in the protection substrate 240. An end section of the lead electrode 202 is located in the through hole 244.

An opening section 246 is formed in the protection substrate 240. The opening section 246 is a space for not obstructing the driving of the piezoelectric element 100. The opening section 246 may be sealed or may not be sealed.

The circuit substrate 250 is provided on the protection substrate 240. The circuit substrate 250 includes semiconductor integrated circuit (IC) for driving the piezoelectric element 100. The circuit substrate 250 and the lead electrode 202 are electrically coupled to each other via the coupling wire 204.

The compliance substrate 260 is provided on the protection substrate 240. The compliance substrate 260 includes a sealing layer 262 provided on the protection substrate 240 and a fixed plate 264 provided on the sealing layer 262. The sealing layer 262 is a layer for sealing the manifold 216. The sealing layer 262 has, for example, flexibility. A through hole 266 is formed in the fixed plate 264. The through hole 266 penetrates the fixed plate 264 in the Z-axis direction. The through hole 266 is provided at a position overlapping the manifold 216 when viewed from the Z-axis direction.

### 4. Printer

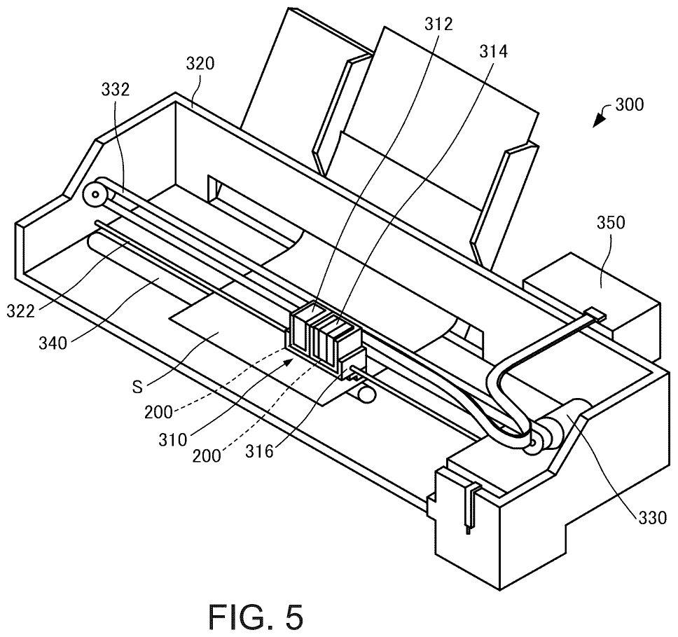

Next, a printer according to the present embodiment will be described with reference to the drawings. FIG. 5 is a perspective view schematically illustrating a printer 300 according to the present embodiment.

The printer 300 is an inkjet printer. As shown in FIG. 5, the printer 300 includes a head unit 310. The head unit 310 includes, for example, the liquid ejection head 200. The number of liquid ejection head 200 is not particularly limited. The head unit 310 is detachably attached with cartridges 312 and 314 constituting a supply unit. A carriage 316 on which the head unit 310 is mounted is provided on a carriage shaft 322 attached to a device main body 320 so as to be movable in the shaft direction, and ejects the liquid supplied from the liquid supply unit.

Here, the term “liquid” refers to a material in a state where a substance is in its liquid phase, and materials in a liquid state such as sol and gel are also encompassed within this term. In addition, the term “liquid” not only refers to a liquid as one state of a substance but also includes substances in which particles of a functional material made of solid materials such as pigments or metal particles are dissolved, dispersed, or mixed in a solvent. Typical examples of liquid include ink and a liquid crystal emulsifier. The ink includes a variety of liquid phase compositions including such as general water-based ink and oil-based ink, gel ink, hot-melt ink, and the like.

In the printer 300, the driving force of the drive motor 330 is transmitted to the carriage 316 via a plurality of gears (not shown) and a timing belt 332, and thus the carriage 316 on which the head unit 310 is mounted is moved along the carriage shaft 322. On the other hand, the device main body 320 is provided with a transport roller 340 as a transport mechanism that moves a sheet S, which is a recording medium such as paper, relative to the liquid ejection head 200. The transport mechanism for transporting the sheet S is not limited to the transport roller, and may be a belt, a drum, or the like.

The printer 300 includes a printer controller 350 as a control section that controls the liquid ejection head 200 and the transport roller 340. The printer controller 350 is electrically coupled to the circuit substrate 250 of the liquid ejection head 200. The printer controller 350 includes, for example, a random access memory (RAM) that temporarily stores various data, a read only memory (ROM) that stores a control program and the like, a central processing unit (CPU), a drive signal generation circuit that generates a drive signal to be supplied to the liquid ejection head 200, and the like.

The piezoelectric element 100 can be used in a wide range of applications without being limited to a liquid ejection head and a printer. The piezoelectric element 100 is suitably used as a piezoelectric actuator of, for example, an ultrasonic motor, a vibration-type dust removing device, a piezoelectric transformer, a piezoelectric speaker, a piezoelectric pump, a pressure-electricity conversion device, and the like. The piezoelectric element 100 is suitably used as, for example, a piezoelectric sensor element such as an ultrasonic wave detector, an angular velocity sensor, an acceleration sensor, a vibration sensor, an inclination sensor, a pressure sensor, a collision sensor, a human detection sensor, an infrared sensor, a terahertz sensor, a heat detection sensor, a pyroelectric sensor, a piezoelectric sensor, and the like. The piezoelectric element 100 is suitably used as a ferroelectric element such as a ferroelectric memory (FeRAM), a ferroelectric transistor (FeFET), a ferroelectric arithmetic circuit (FeLogic), a ferroelectric capacitor, and the like. Further, the piezoelectric element 100 is suitably used as a voltage-controlled optical element such as a wavelength converter, an optical waveguide, an optical path modulator, a refractive index control element, an electronic shutter mechanism, and the like.

### 5. Implementation Examples and Comparative Examples

### 5.1. Preparation of Sample

### 5.1.1. Example 1

The surfaces of the single crystal silicon substrates were thermally oxidized to form SiO2 layers having 1460 nm thickness. Next, a Zr film having a 400 nm thickness was formed by direct current (DC) sputtering, and a Zro₂ layer was formed by heat treatment at 850° C.

Next, on the Zro₂ layer, a Ti layer having a thickness of 20 nm, a Pt layer having a thickness of 80 nm, and an Ir layer having a thickness of 5 nm were formed as a first electrode by a DC sputtering method.

Next, precursor solutions were blended so as to have a molar ratio of Bi:Pb:Fe:Ti=110:10:50:50. The blended precursor solutions were applied onto the Ir layer and the ZrO₂ layer by spin coating, dried at 180° C. for 3 minutes, degreased at 380° C. for 3 minutes, and baked at 650° C. for 3 minutes. Lamp annealing was used for sintering. By this, a BFTP layer having a thickness of 20 nm was formed.

Next, precursor solutions composed of potassium 2-ethylhexanoate, sodium 2-ethylhexanoate, lithium 2-ethylhexanoate, niobium 2-ethylhexanoate, manganese 2-ethylhexanoate, and copper 2-ethylhexanoate were used to blend a K_{0.5136}Na_{0.4934}Li_{0.053}Nb_{0.99}Mn_{0.005}Cu_{0.005}Oₓ (where x is any number greater than 0). Then, the blended precursor solution was applied onto the BFTP layer by a spin coating method, dried at 180° C. for 3 minutes, degreased at 380° C. for 3 minutes, and baked at 700° C. for 3 minutes. For sintering, lamp annealing was used in which the heating rate of temperature increase was 10° C./sec and has lamps disposed above and below the sample. During sintering, an oxygen flow at a mass flow rate of 3 SLPM was applied to the upper portion of the sample. By this, a crystalline layer with a thickness of 80 nm was formed. The series of steps from the application of the precursor solution to sintering the precursor layer was repeated five times to form a piezoelectric layer composed of five crystalline layers.

Next, a Pt layer having a thickness of 50 nm was formed on the piezoelectric layer by a DC sputtering method. Thereafter, the Pt layer was patterned by photolithography and etching to form a second electrode.

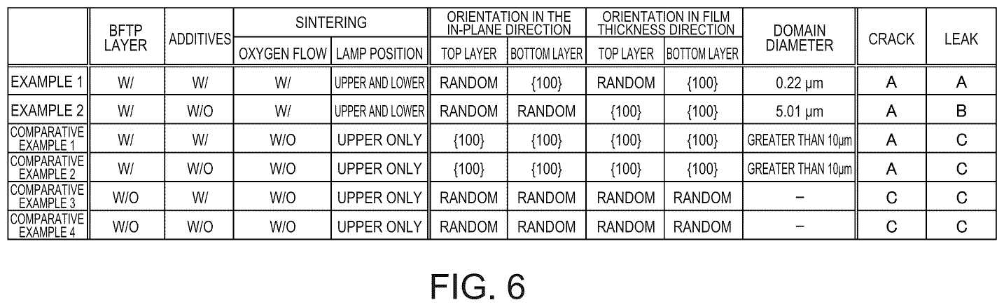

As described above, the piezoelectric element of Example 1 was formed. FIG. 6 is a table showing production conditions of Example 1, and Example 2 and Comparative Examples 1 to 4 to be described later. In FIG. 6, “additive” refers to lithium, manganese, and copper.

### 5.1.2. Example 2

A piezoelectric element of Example 2 was formed by the same method as that of Example 1 except that the composition of the crystalline layer was K_{0.50}Na_{0.50}Nb_{1.00}Oₓ.

### 5.1.3. Comparative Example 1

No oxygen flow was used during sintering. Note that before sintering, the chamber of the RTA apparatus performed oxygen substitution with 0.1 SLPM for 10 seconds. Sintering was performed by lamp annealing from only the top of the sample rather than from the bottom of the sample.

A piezoelectric element of Comparative Example 1 was formed in the same manner as in Example 1 except for the above.

### 5.1.4. Comparative Example 2

A piezoelectric element of Comparative Example 2 was formed by the same manner as that of Comparative Example 1, except that the composition of the crystalline layer was K_{0.50}Na_{0.50}Nb_{1.00}Oₓ.

### 5.1.5. Comparative Example 3

A piezoelectric element of Comparative Example 3 was formed in the same manner as that of Comparative Example 1, except that the BFTP layer was not formed.

### 5.1.6. Comparative Example 4

A piezoelectric element of Comparative Example 4 was formed by the same manner as that of Comparative Example 1, except that the composition of the crystalline layer was K_{0.50}Na_{0.50}Nb_{1.00}Oₓ and the BFTP layer was not formed.

### 5.2. Experimental Method

### 5.2.1 Orientation Ratio

Orientation ratios of the lowermost crystalline layer and the uppermost crystalline layer (hereinafter, also simply referred to as “lowermost layer” and “uppermost layer” of the plurality of crystalline layers were measured. The orientation ratio of the lowermost layer was measured after the first crystalline layer was formed and before the second crystalline layer was formed. The orientation ratio of the uppermost layer was measured after the fifth crystalline layer was formed and before the Pt layer was formed.

As a measurement apparatus, EBSD manufactured by Oxford Instruments plc was used. “AZtec Crystal” was used as the analysis software. The measuring region was a 50 μm×50 μm. Each orientation region was designated in the “Texture Components” mode for EBSD in the measuring region. Each orientation composition was “defined by fiber axis”.

The orientation ratio in the film thickness direction was designated and measured as follows.
100 ORIENTATION: <100>∥Z0
110 ORIENTATION: <110>∥Z0
111 ORIENTATION: <111>∥Z0

The orientation ratio in the in-plane direction was designated and measured as follows.
100 ORIENTATION: <100>∥X0
110 ORIENTATION: <110>∥X0
111 ORIENTATION: <111>∥X0

The deviation angle, in other words, the allowable range of deviation from the designated direction, was set as 15°.

In FIG. 6, the {100} preferred orientation is represented by “{100}”, and the random orientation is represented by “random”. In FIG. 6, “{100}” indicates that the orientation ratio of the {100} plane is 95% or more.

### 5.2.2. Domain Diameter

The domain diameter in the in-plane direction of the uppermost layer was measured using the measurement apparatus and the analysis software used for measuring the orientation ratio. The size of the measuring region is the same as the size in the measurement of the orientation ratio. For the EBSD data in the in-plane direction of the uppermost layer, the domain diameter was measured in the “grain size analysis mode”. The “threshold” for distinguishing orientation was taken as 8°, and boundary particles were excluded.

The average size of all the domains targeted in the above-described setting was defined as the domain diameter.

### 5.2.3. Crack

The presence or absence of cracks in the uppermost layer was evaluated by dark-field observation with a metallurgical microscope. In FIG. 6, “A” indicates that no crack occurred in the uppermost layer, and “C” indicates that a crack occurred in the uppermost layer.

### 5.2.4. Leakage Current

The leakage current was measured by evaluating the IV characteristics. As the measuring apparatus, “4140B” manufactured by Keisight Co. was used. Measurement condition was 1 to 40 V/1 Vstep, 10 second_delay/step. The first electrode was set as the drive electrode. In FIG. 6, “A” indicates that the leakage current is less than or equal to 1×10⁻⁶ A/cm², “B” indicates that the leakage current is greater than that of 1×10⁻⁶ A/cm² and less than or equal to 1×10⁻⁵ A/cm², and “C” indicates that the leakage current is greater than that of 1×10⁻⁵ A/cm².

### 5.3. Experimental Results

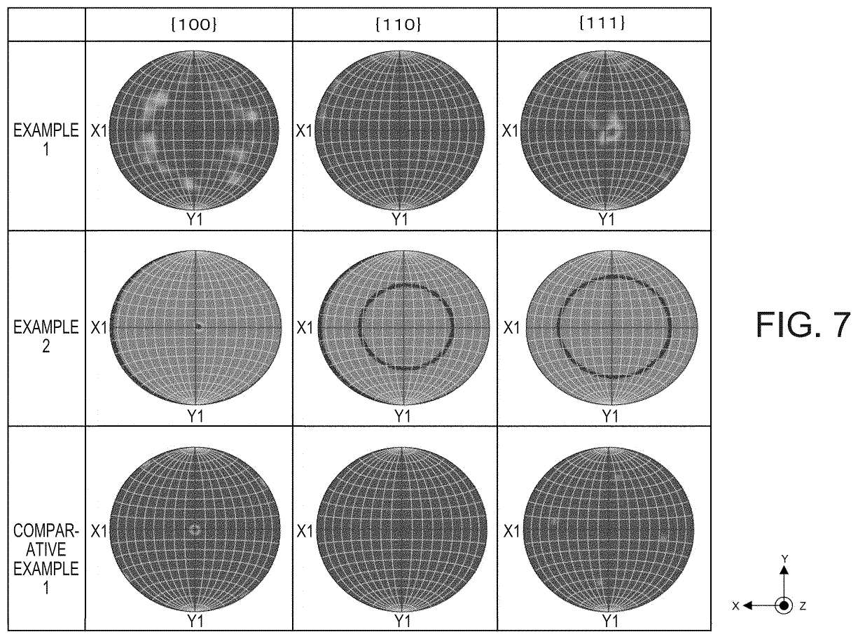

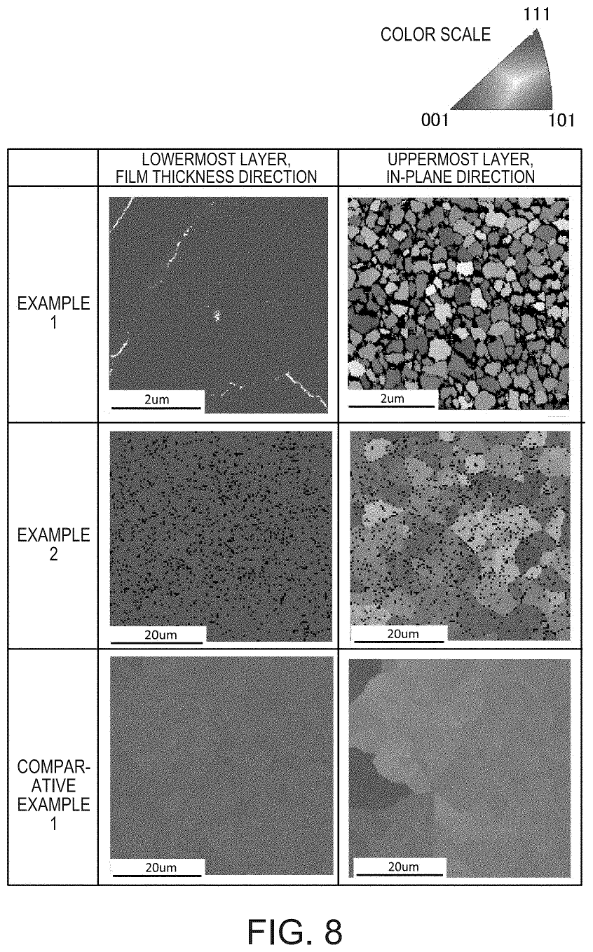

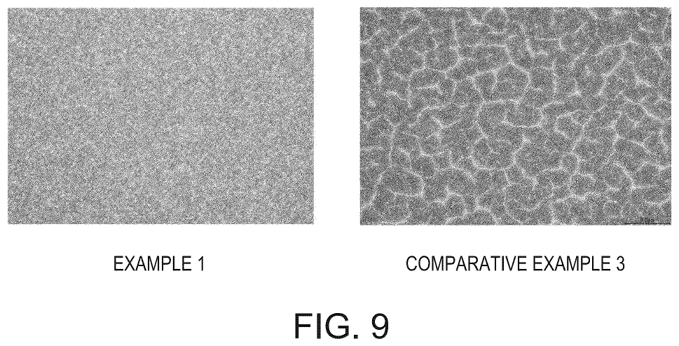

FIG. 6 shows the results of the orientation ratio measurement, the domain diameter measurement, the crack evaluation, and the leakage current evaluation. FIG. 7 is a pole figure of Examples 1 and 2 and Comparative Example 1 by EBSD. FIG. 8 is a domain observation map of Examples 1 and 2 and Comparative Example 1 by EBSD. The orientations and the domain diameters shown in FIG. 6 are calculated based on FIGS. 7 and 8.” FIG. 9 shows metallographical micrographs of Example 1 and Comparative Example 3. In FIG. 9, cracks are confirmed as white streak-like regions.

As shown in FIG. 6, in Examples 1 and 2 and Comparative Examples 1 and 2 in which the BFTP layer was formed, the lowermost layer is preferred orientation in the {100} plane in the film thickness direction. No cracks were observed in Examples 1 and 2 and Comparative Examples 1 and 2 in which the lowermost layer was preferred orientation in the {100} plane in the film thickness direction. Therefore, it was found that when the lowermost layer was preferred orientation to the {100} plane in the film thickness direction, the occurrence of cracks could be suppressed.

In Examples 1 and 2, in which the uppermost layer was randomly oriented in the in-plane direction, the leakage current was small. In Comparative Examples 3 and 4, the uppermost layer was randomly oriented in the in-plane direction, but a crack was generated, so that the crack became a leak path, and the leak current was large. In Example 1 in which the additive was added, the leakage current could be reduced as compared with Example 2 in which the additive was not added. It was found that the additive contributes to a reduction in leakage current.

In Examples 1 and 2, in which the uppermost layer was randomly oriented in the in-plane direction, the domain diameter was smaller than that in Comparative Examples 1 and 2. It was found that when the domain diameter was small, the uppermost layer was easily randomly oriented in the in-plane direction.

The above-described embodiments and modifications are merely examples, and the present disclosure is not limited thereto. For example, the embodiments and the modifications may be combined as appropriate.

The disclosure includes a configuration which is substantially the same as the configuration described in the embodiment, for example, a configuration having the same function, method, and result, or a configuration having the same object and effect. In addition, the present disclosure includes a configuration in which a non-essential portion of the configuration described in the embodiment is replaced. In addition, the present disclosure includes a configuration having the same operational effects as the configuration described in the embodiment or a configuration capable of achieving the same object. In addition, the present disclosure includes a configuration in which a known technology is added to the configuration described in the embodiment.

The following contents are derived from the above-described embodiment and modifications.

One aspect of the piezoelectric element includes
a first electrode and a second electrode and
a piezoelectric layer provided between the first electrode and the second electrode, the piezoelectric layer including a plurality of layers containing a composite oxide having a perovskite structure containing potassium, sodium, and niobium; wherein
among the plurality of layers including the composite oxide, a first layer closest to the first electrode is preferred orientation in a first orientation, which is a {100} plane orientation in a film thickness direction,
among the plurality of layers including the composite oxide, a second layer closest to the second electrode is, in an in-plane direction intersecting the film thickness direction, a mix of the first orientation and a second orientation, which is a {110} plane orientation, and is not preferred orientation in either the first orientation or the second orientation.

According to the piezoelectric element, leakage current can be reduced.

An aspect of the piezoelectric element may be such that the second layer may be, in the in-plane direction, a mix of the first orientation, the second orientation, and a third orientation, which is a {111} plane orientation, and be not preferred orientation in the third orientation.

According to this piezoelectric element, it is possible to suppress generation of a grain boundary which may become a leak path connected from the first electrode to the second electrode in the film thickness direction.

An aspect of the piezoelectric element may be such that the second layer may be preferred orientation in the first orientation in the film thickness direction.

According to this piezoelectric element, in the second layer, it is possible to reduce stress generated in a grain boundary with a different orientation different from the first orientation.

An aspect of the piezoelectric element may be such that the piezoelectric element may further include an orientation control layer that is provided between the first electrode and the first layer and that includes bismuth, iron, titanium, and lead.

According to this piezoelectric element, the orientation of the first layer can be controlled.

An aspect of the piezoelectric element may be such that A domain diameter of the second layer in the in-plane direction may be less than or equal to 5.01 μm.

According to this piezoelectric element, the second layer can be randomly oriented in the in-plane direction.

An aspect of the piezoelectric element may be such that a domain diameter of the second layer in the in-plane direction may be less than or equal to 0.22 μm.

According to this piezoelectric element, the second layer can be randomly oriented in the in-plane direction.

An aspect of the liquid ejection head includes the aspect of the piezoelectric element;
a channel forming substrate in which a pressure generating chamber whose volume is changed by the piezoelectric element is formed; and
a nozzle plate in which a nozzle hole communicating with the pressure generating chamber is formed.

One aspect of the printer includes one aspect of the liquid ejection head;
a transport mechanism configured to perform relative movement a recording medium with respect to the liquid ejection head; and
a control section that controls the liquid ejection head and the transport mechanism.

What is claimed is:

1. A piezoelectric element comprising:
a first electrode and a second electrode and
a piezoelectric layer provided between the first electrode and the second electrode, the piezoelectric layer including a plurality of layers containing a composite oxide having a perovskite structure containing potassium, sodium, and niobium; wherein
among the plurality of layers including the composite oxide, a first layer closest to the first electrode is preferred orientation in a first orientation, which is a {100} plane orientation in a film thickness direction,
among the plurality of layers including the composite oxide, a second layer closest to the second electrode is, in an in-plane direction intersecting the film thickness direction, a mix of the first orientation and a second orientation, which is a {110} plane orientation, and is not preferred orientation in either the first orientation or the second orientation.

2. The piezoelectric element according to claim 1 wherein
the second layer is, in the in-plane direction, a mix of the first orientation, the second orientation, and a third orientation, which is a {111} plane orientation, and is not preferred orientation in the third orientation.

3. The piezoelectric element according to claim 1 wherein
the second layer is preferred orientation in the first orientation in the film thickness direction.

4. The piezoelectric element according to claim 1, further comprising:
an orientation control layer that is provided between the first electrode and the first layer and that includes bismuth, iron, titanium, and lead.

5. The piezoelectric element according to claim 1 wherein
a domain diameter of the second layer in the in-plane direction is 5.01 μm or less.

6. The piezoelectric element according to claim 5 wherein
the domain diameter of the second layer in the in-plane direction is 0.22 μm or less.

7. A liquid ejection head comprising:
the piezoelectric element according to claim 1;
a channel forming substrate in which a pressure generating chamber whose volume is changed by the piezoelectric element is formed; and
a nozzle plate in which a nozzle hole communicating with the pressure generating chamber is formed.

8. A printer comprising:
the liquid ejection head according to claim 7;
a transport mechanism configured to perform relative movement a recording medium with respect to the liquid ejection head; and
a control section that controls the liquid ejection head and the transport mechanism.
